(19) United States
(12) Patent Application Publication
(10) Pub. No.: US 2007/0253255 A1
(43) Pub. Date: Nov. 1, 2007

(54) Memory device, method for sensing a current output from a selected memory cell and sensing circuit

(76) Inventors: Girolamo Gallo, Padova (IT); Giorgio Oddone, Monselice (IT); Alberto Taddeo, Arenzano (IT); Carmelo Giunta, Barcellona Pozzo di Gotto(Me) (IT); Marco Carminati, Segrate (Mi) (IT)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/414,622

(22) Filed: Apr. 28, 2006

(51) Int. Cl. G11C 11/34; G11C 16/06

(52) U.S. Cl. 365/185.21

(57) ABSTRACT

A memory device, a method for sensing a current output and a sensing circuit are disclosed. In one embodiment, a first voltage is supplied at least to a drain and a source terminal of a neighboring memory cell before sensing, and the first voltage is applied to a source terminal of a selected memory cell, while sensing the current though the selected memory cell.

### FIELD OF INVENTION

A memory device, a method for sensing a current output and a sensing circuit are described, whereby a first voltage is supplied at least to a drain and a source terminal of a neighboring memory cell before sensing, and the first voltage is applied to a source terminal of a selected memory cell, while sensing the current though the selected memory cell.

### BACKGROUND

In memory devices memory cells are arranged in an array consisting of rows and columns, whereby each memory cell is identified by a certain row and a certain column. FIG. 7 illustrates schematically such an array 1 which comprises a certain amount of memory cells 2, which mainly are based on MOSFET-type devices, which have a control terminal 3, a drain terminal 4 and a source terminal 5. All control terminals 3 of MOSFETs, which are arranged in a row are connected to a row decoder 10 via a separate wordline 11. The source terminals of memory cells, which are situated in one column are normally connected together via bitlines 12 and are addressed via a column multiplexer 13. In the embodiment of FIG. 7, the drain terminals 4 of memory cells, which are situated in one column, are also connected together via bitlines, whereby the source terminal 5 of one memory cell is connected to the drain terminal 4 of a neighboring memory cell. In one embodiment, memory cells are based on so-called NROM, whereby an NROM cell is a n-channel MOSFET device where the gate dielectric is replaced with trapping material (nitride) sandwiched between two silicon dioxide layers. The charge is stored in the nitride above the channel next to the n-junctions. The top and bottom oxides are thick enough to prevent a direct tunneling of this charge.

The sensing, whether such a memory cell is in a conducting or non-conducting state, is done by applying a drain voltage by approximately 1.6 V and a source voltage of approximately 200 mV. The source current is then measured via a sense amplifier 20, which compares the source current Imeas with a reference current Iref. The reference current Iref is determined by applying the same voltages to a reference cell (not depicted). However, in this measuring scheme there is a certain current Ineigh also flowing through the neighboring memory cell which disturbs the measuring of the source current Icell of the selected memory cell.

As it is depicted in FIG. 8 the array of memory cells may be divided into several sub-arrays or slices , which are isolated from one another by slice isolations 23. Each slice is connected via two global bitlines GBL, GBL+1 to which, in the example of FIG. 8, in total eight selection transistors sel0, . . . , sel7 are provided to contact nine local bitlines lbl0, . . . , lbl8. With the help of the selection transistors sel0, . . . , sel7 the local bitlines lbl0, . . . , lbl8 are addressed and so are the respective memory cells, which are connected to the local bitlines.

When reading, through a source sensing circuitry as described, a sliced NROM array, the neighbor current Ineigh, that is the current flowing through the cell placed on the same row and on an adjacent column of the selected memory cell, may become a major concern and affect the sensed current Imeas. As the neighbor current Ineigh does not match a reference current Iref, provided by a reference cell, over all supply voltages and temperatures and varies depending on the state of the neighbor cell, such an effect may significantly degrade the sensing read margins.

For these and other reasons, there is a need for the present invention.

### SUMMARY

The present invention provides a memory device, a method for sensing a current output and a sensing circuit. In one embodiment, a first voltage is supplied at least to a drain and a source terminal of a neighboring memory cell before sensing, and the first voltage is applied to a source terminal of a selected memory cell, while sensing the current though the selected memory cell.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a timing diagram for the read operation.

FIG. 2 illustrates a first embodiment of a sensing circuit with a pre-charge circuit and an I-V conversion circuit.

FIG. 3 illustrates a more precise circuit of the first embodiment,

FIG. 4A illustrates a circuit of a first option to stabilize the first potential

FIG. 4B illustrates a circuit for a second option to stabilize the first potential,

FIG. 5A illustrates a circuit of a first option to generate the cascode voltage.

FIG. 5B illustrates a circuit of a second option to generate the cascode voltage.

FIG. 6 illustrates a circuit of a second embodiment of the sensing circuit.

FIG. 7 illustrates schematically an array of memory cells with a sense amplifier to measure the current of the memory cells as prior art.

FIG. 8 illustrates an isolated slice of an array of the memory cells as prior art.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The present invention provides a first embodiment a memory device is described, which comprises a plurality of memory cells, whereby each memory cell comprises a drain terminal and a source terminal, the memory cells being arranged in an array of rows and columns, whereby the source terminals of the memory cells arranged in one of the columns are connected via respective bitlines, whereby a voltage supply for providing a first voltage to every bitline of the memory device before sensing the condition of a selected memory cell is provided, which also provides a second voltage to the drain terminal of the selected memory cell and a sensing device for sensing the current output of the drain terminal of the selected memory cell. With this approach it is ensured, that before starting the actual sensing operation all the bitlines located in the addressed slice are pre-charged to the same voltage, also used to bias the memory cell source terminal. Thereby the drain/source voltage of the neighboring memory cell is minimized and, therefore as well, the neighboring current Ineigh.

In a one embodiment a sensing circuit is provided, which includes two sections, whereby the first section is a pre-charge circuit to apply the first potential to the source terminals and the second section is an I-V conversion circuit to translate a measured source current into a voltage signal. This circuit is capable of directly measuring the source current of a NROM memory cell and it is designed to be operated at very low supply voltages, e.g., 1.8V. As a result the sensing operation does not critically depend on the matching of parasitic components.

The approach can be used to implement the global sensing scheme, where one single reference cell can be used by several sense amplifiers, with a drastic reduction of the number of reference cells to be programmed at wafer sorting and a significant power consumption saving during the read operation.

In another embodiment a sensing circuit is provided, which includes a local feedback cascode, which stabilizes a first potential and which is connected to the bitlines of the memory cell, the local feedback cascode comprises a cascode transistor, which gate is controlled via an operational amplifier output, which on its input compare the voltage at the bitlines with a predetermined voltage value, and which source terminal is contacted to the bitlines and to a sink transistor acting as a current sink for a bias current, and which drain terminal is contacted with the source terminal of a first PMOS mirror transistor, which provides a current that is the bias current minus the current through a reference cell. The local feedback cascode ensures fast bitline pre-charging. The I-V conversion, to translate the measured current into a voltage signal, is achieved with this sensing circuit.

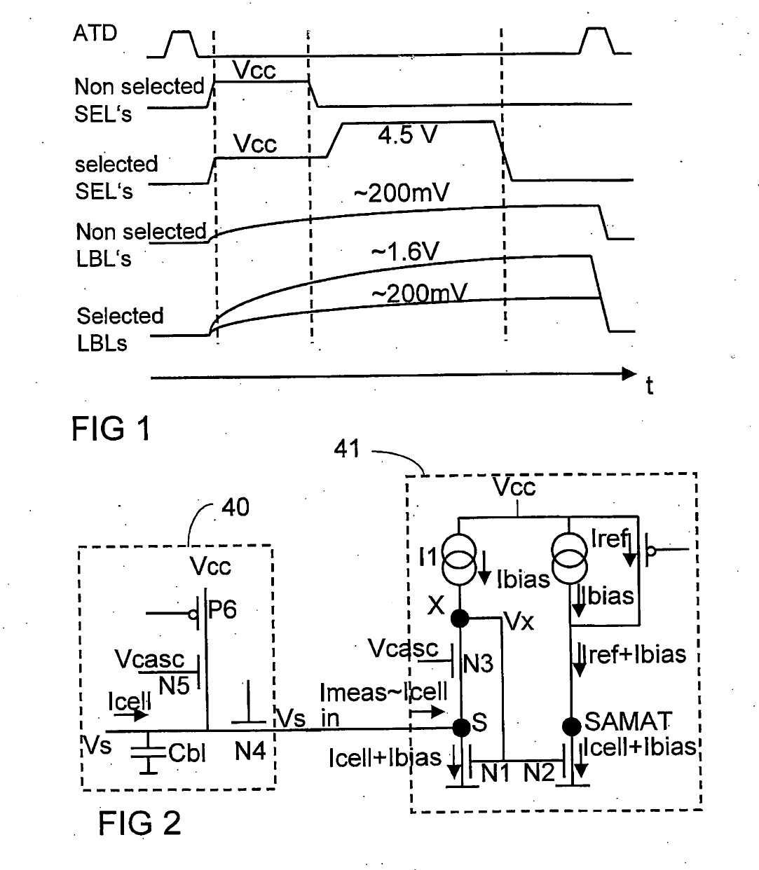

FIG. 1 illustrates one embodiment of a timing diagram of the a operation according to the present invention. The read operation of a selected memory cell starts with the reception of an address transition detection (ATD) pulse. After reception of this ATD-pulse the selection transistors sel0, . . . , sel8, which provide the connection of the local bitlines lbl0, . . . , lbl9 to the global bitlines GBL, GBL+1, either they belong to the selected memory cell (“selected”) or not (“not selected”) are all provided with the supply voltage VCC thereby ensuring that the voltage on all bitlines (the selected local bitlines as well as the non-selected local bitlines) is increasing towards the source voltage value of 200 mV. During the following phase the local bitline lbl and global bitline GBL connected to the selected memory cell source are driven to the source voltage Vs, while all the other bitlines are left floating to the source voltage value Vs. The global bitline GBL connected to the drain terminal of the selected memory cell is disconnected from the voltage source, which provides the source voltage Vs, and tight to the cell drain bias voltage VD=1,6 V. At the end of the read operation, the two global bitlines GBL, GBL+1 are re-connected either to the source voltage value Vs (if another access is to be performed in the same slice) or to ground, while all the control terminals or gates of the selected transistors are connected to the power supply. As a result, during the sensing operation, the drain/source voltage Vds of the neighbor memory cell is close to 0 V, making the current Ineigh through the neighbor memory cell negligible.

The proposed method can be extended also to a larger NROM array structure intended for data flash storage. Such an array architecture includes eight or sixteen slices per sense amplifier, thirty-two or more NROM cells per slice and more than two (typical six) global bitlines per slice. All the bits of one memory page (2 kB) are located on the same wordline, which connected the gate terminals of the memory cells.

In such a case the applied timing sequence is very similar to the one described above. During the initial latency, all the global and local bitlines of the addressed slice are pre-charged to the source voltage VS. According to the access time requirements of a data flash, this process can be accomplished very slowly (e.g., in 1 to 4 μs), in order to limit current peaks on the power supply.

Then, similarly to what is described above, once the pre-charge phase is completed, the select transistors are switched off, except the two selected transistors that connect the source and drain terminals of the selected NROM memory cell and are connected to 4.5V. The global bitline connected to the cell drain is disconnected from the source voltage Vs source and tight to the cell drain bias voltage Vd.

Once the first read cycle of the memory page is completed, all the global bitlines are re-connected to the source voltage Vs and all the selected transistors are activated (connecting their gates to the power supply VCC=1.8 V).

The global bitlines GBL, GBL+1 and the related local bitlines which during the previous access were connected to the cell drain are discharged to the source voltage value Vs, while the others are only refreshed to this value.

FIG. 2 illustrates a static sensing circuit based on a reference cell serving several source-side sense amplifiers (global sensing concept).

The circuit can be operated at supply voltages as low as 1.6 V and it is made of two main sections:

A fast pre-charge circuit 40 which is used to set the source bitline and the. neighbor bitlines to the source voltage value Vs (Vs=Vcasc−Vtn5˜200 mV), via the path composed by a first cascode transistor N5 (with threshold voltage Vtn5) and a first PMOS transistor P6. The one purpose of this circuit is to perform the fast bitline pre-charge with very limited power consumption, since while it is operated the I-V conversion section is switched off.

The second section is an I-V conversion circuit 41, which translates the measured current into a voltage signal. The circuit is self-biased by the connection of the gate of the n- channel mirror transistors N1, N2 to the voltage Vx, without the need of generating an additional biasing voltage.

The global sensing approach results into a drastic reduction of the number of reference cells to be programmed at wafer sorting as well as in a significant power consumption saving during the read operation (less bitlines to be pre-charged).

Static sensing, that is a DC measure of the cell current, does not critically depends on the matching of parasitic components (array versus reference bitline capacitance).

The pre-charging circuit 40 is activated at the beginning of the read operation, when a connecting transistor N4 is kept off and the I-V conversion section is also off (bias=0). In this condition, all the global and local bitlines are pre-charged to the source voltage value VS. Therefore, at this time the source/drain voltage Vds=0 and the cell current is Icell=0. As a result, there is no power consumption from the I-V conversion section during the pre-charged phase. A typical duration of this phase is around 10-20 ns, depending on the capacitance of the global bitline.

Once the bitline pre-charge phase is almost completed (e.g., 5-10 ns before its end), the I-V conversion circuit, which translates the measured current Imeas=Icell−Ineigh into a voltage signal is switched on (by Vpbias=0), while the connecting transistor N4 is still off. The circuit is designed with a first cascode transistor N5 being equal to a second cascode transistor N3 (with threshold voltage Vtn3). Due to the very low capacitance of the cascode voltage node (10-20 fF) compared to that of the global and the local bitlines (1-2 pF) the node VS_in reaches very quickly its steady voltage level VS_in=Vcasc−VTN3−Voverdrive<Vs, even if Ibias is very small (ca. 10 μA). If the first cascode transistor N3 is properly sized, at this time the two voltages VS_in and VS differs by no more than few tenth of mV.

At the end of the pre-charged phase the first PMOS transistor P6 is switched off and the connecting transistor N4 is turned on.

At this time, all global and local bitlines are floated to the source voltage value VS except the source bitline, which is driven to VS and the drain bitline, which is now connected to the drain voltage VD˜1.6 V. When the connecting transistor N4 is turned on, the source voltage value VS>VS_in. The first NMOS mirror transistor N1 provides a discharge path that ensure the fast Vs settling time to VS_in. After a short period of time (10-20 ns depending on the global bitline capacitance), the two nodes VS_in and VS are stable at the same voltage and the I-V conversion is achieved on the node SAMAT, by comparing the two currents Imeas+Ibias and Iref+Ibias.

The NROM source bias voltage VS during the read operation is critical to achieve “close to ground sensing”, VS=200 mV has been considered as a good trade-off to satisfy the following constraints:

The source voltage value VS has to be as close as possible to the ground voltage for two reasons: a) to limit the second bit effect, the cell to be read should be biased in the saturation region with a minimum drain/source voltage VDS of around 1.4 V. In addition the drain/source voltage VDS should not exceed 1.4 V for limiting any “read disturbed” phenomena, b) to reduce the neighbor current Ineigh component, that is the current generated by the selected cell and that flows into the sensing node and effects the result of the sensing operation. Being the current measured by the sense amplifier Imeas=Icell−Ineigh, a high neighboring current could affect the sensing margins, because the neighboring current variation with temperature and with supply voltage VCC is not matched by the referenced current through the reference cell.

The source voltage value VS should be set high enough to guarantee that the first mirror transistor N1 is in saturation, being N1 the left side branch of a NMOS current mirror. In the proposed implementation, the source voltage value VS is said to 200 mV by the common gate amplifier made of the cascode transistor N3 and the current generator I1, having the source voltage value Vs as input and Vx as output. The cascode voltage Vcasc˜200 mV+Vtn3+Voverdrive is a fixed bias provided by a voltage generator.

The I-V conversion is fast, being the point SAMAT, capacitively decoupled from the source bitline S, which is much more capacitive (ca. 1-2 pF). Being the SAMAT capacitance small, transitions of this node are sharp even if the difference between the cell current Icell and the reference current Irel (Icell-Iref) is small.

As the bias current ibias is added both to the measured current Imeas and the reference current Iref, its value does not effect the correctness of the read operation.

The reference current Iref is generated by a reference NROM cell, having an intermediate threshold voltage Vth and intermediate drain/source current Ids between both of an erased and a programmed NROM cell. The reference current Iref is mirrored by a reference sense amplifier circuit, similar to the one depicted in FIG. 2, to the sense amplifier of the array. This guarantees that reference current Iref tracks the cell current Icell over all temperature, supply voltage VCC and process comers.

This circuit is particularly suitable for implementing a global sensing scheme. Therefore one single reference cell can be used by several sense amplifiers, thus drastically reducing the number of reference cells to be programmed at wafer sorting as well as the memory power consumption during the read operation.

Fast pre-charge to around 200 mV of the source bitline via the pre-charged circuitry is advantageous. During the pre-charged time, the I-V conversion circuit can be switched off to reduce the power consumption and can be disconnected from the source bitline via the connecting transistor N4. The pre-charged voltage value of the slice is close to the cascode voltage Vcasc-Vtn5 as the slice is just a capacitive load, and it is therefore higher than the DC bias after the connecting transistor N4 is switched on. This ensures a fast settling time for the source voltage value VS when the connecting transistor N4 is turned on as a discharge path is provided by the first mirror transistor N1.

A good compromise is achievable between the source voltage value Vs setting time and power consumption. A 10 mA bias current Ibias allows to satisfy even the access time specification of the code flash (70 ns).

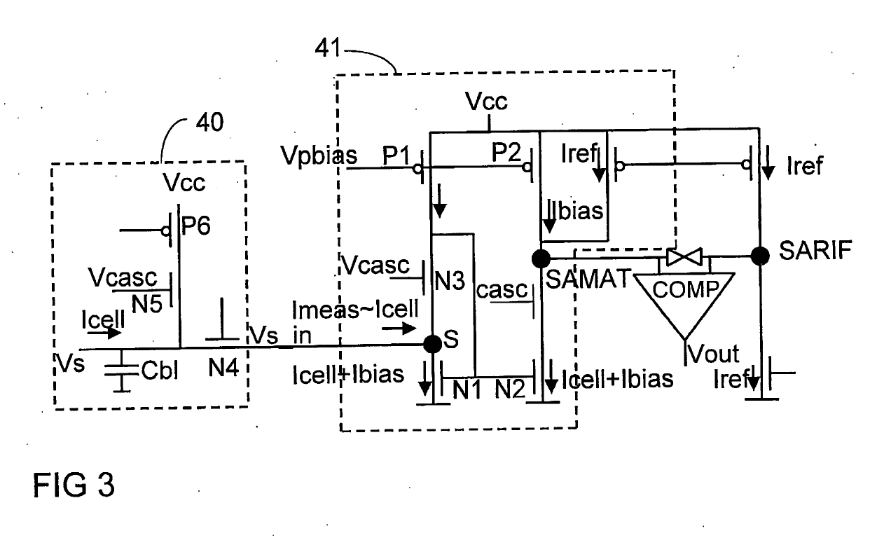

The bias current Ibias absolute value accuracy is not mandatory. A current bias Ibias supplied by saturated first and second PMOS transistors P1 and P2 (see FIG. 3) are very well matched being, that the first and second PMOS transistors P1 and P2 being close to each other.

An additional comparator COMP in FIG. 3 speeds up the analogue to digital conversion from VSAMAT to Vout. An equalization is provided between the two nodes SAMAT and SARIF. The comparator COMP is switched on, when the equalization signal is released: from that time the SAMAT node will start evolving according to the status of the read cell.

The proposed sense amplifier achieves an access time of 70 ns, the maximum power consumption being lower than 55 mW (average on the read cycle). Moreover, the full slice pre-charge method to 200 mV allows to reduce the neighbor current below 500 nA.

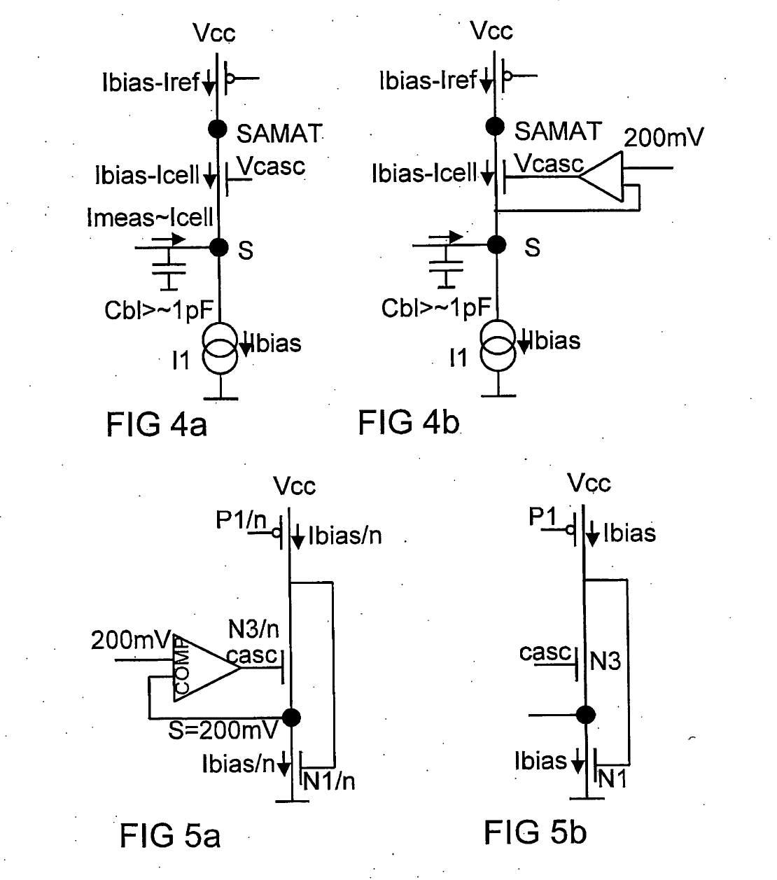

FIGS. 4a and 4b illustrate different options for regulating the source voltage value Vs. FIG. 4b depicts the solution as described with respect to FIGS. 2 and 3, whereas as an alternative in FIG. 4a can be used. In this option, the source voltage value Vs is set to 200 mV by the common gate amplifier made of the transistor N3 and the current generator I1, where the cascode voltage Vcasc (Vcasc˜200 mV+Vtn3+Voverdrive) is a fixed bias provided by a voltage generator. This ensures a lower power consumption at the expense of a slower bitline pre-charge.

In order to reduce the variation on signal cascode voltage Vcasc due to simultaneous switching of several sensing amplifiers, a 200 fF capacitor can be placed close to the gate of the first cascode transistor N3 of each sense amplifier.

To make the circuit operation independent on temperature variations, the bias voltage Vbias signal is generated by the circuit shown in FIG. 5A (instead of the circuit depicted in FIG. 5b). To reduce the circuit power consumption during stand-by, the biasing circuit is designed with using a transistor width divided by a factor of N.

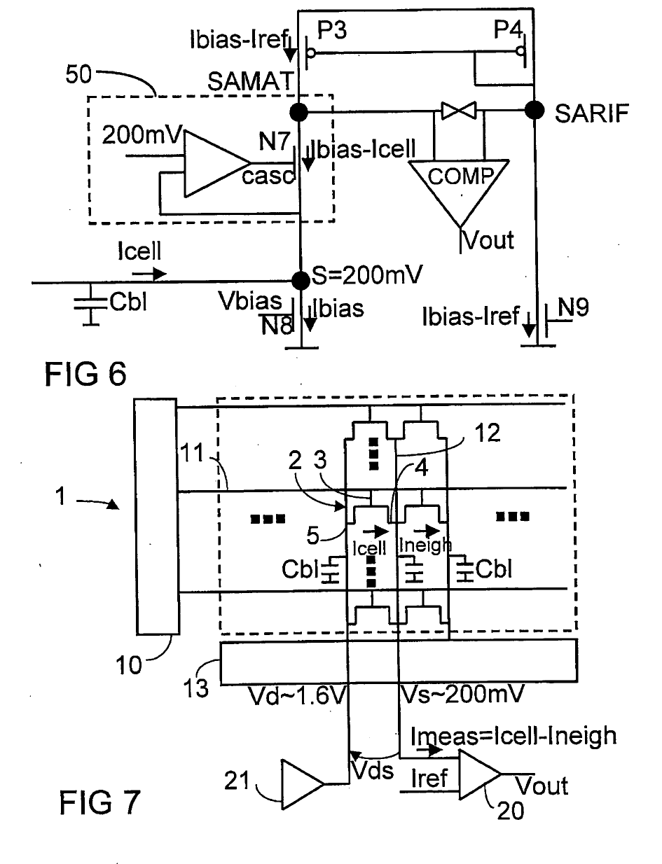

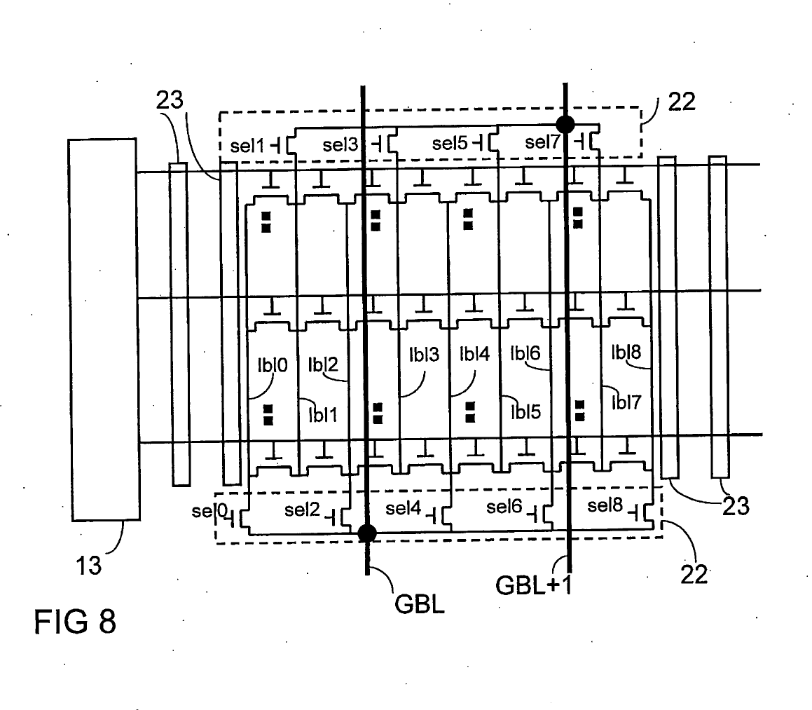

A second embodiment of a sensing circuit is depicted in FIG. 6. A local feedback cascode 50 ensures fast bitline pre-charging to a source voltage value of 200 mV via the path composed by the third cascode voltage transistor N7 and the first PMOS mirror transistor P3. The purpose of this section is to perform a fast bitline pre-charge.

The I-V conversion, to translate the measured current Imeas=Icell−Ineigh (with Ineigh˜0) into a voltage signal, is achieved on the node SAMAT, where the two currents Ibias-Imeas and Ibias-Iref are compared. The N channel transistor N8 is biased into saturation and acts as a current generator, which sinks a constant current Ibias.

The I-V conversion is fast, being that the node SAMAT is capacitively decoupled from the source bitlines, which is much more capacitive (ca. 1 pF). As the SAMAT capacitance is small, the transitions on this node are sharp even if Icell-Iref is small.

Since the bias current Ibias offset is added both to Imeas and Iref, its value does not effect that correctness of the read operation.

As an alternative, the pre-charged scheme depicted in FIG. 4A can be used instead of the local feedback cascode (FIG. 4B), as has been explained already above.

The circuit of the second embodiment ensures the fast pre-charge to about 200 mV of the source bitline. If a local feedback loop is used (FIG. 4B), the pre-charge is faster at the expense of a higher current consumption.

An additional comparator COMP in FIG. 6, speeds up the analogue to digital conversion from V(SAMAT) to Vout. An equalization is provided between nodes SAMAT and SARIF. The comparator COMP is switched on when the equalization signal is released: from that time, the node SAMAT will start evolve according to the state (erased or programmed) of the read cell.

The proposed sense amplifier of the second embodiment achieves an access time of 70 ns (matching the specifications of state of the art coat flash memories), the power consumption being lower than 95 mW (average on a read cycle) when a feedback cascode circuit is used. Moreover, the fault slice pre-charge 2 to 200 mW method allows to reduce the neighboring current below 700 nA.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A memory device comprising:
a plurality of memory cells, whereby each memory cell comprises a drain terminal and a source terminal, the memory cells being arranged in an array of rows and columns, whereby the source terminals of the memory cells arranged in one of the columns are connected via respective bitlines;
a voltage supply for providing a first voltage to every bitline of the memory device before sensing the condition of a selected memory cell, and for providing a second voltage to the drain terminal of the selected memory cell; and
a sensing device for sensing the current output of the source terminal of the selected memory cell.

2. The memory device according to claim 1, whereby the source terminals of one column are drain terminals of adjacent columns of memory cells.

3. The memory device according to claim 1, whereby the first potential is different from ground potential.

4. The memory device according to claim 1, whereby the first potential is around 200 mV.

5. The memory device according to claim 1, whereby the memory cells are separated into blocks, each block comprises two global bitlines and for each column one local bitline to address the memory cells, the memory device further comprising a switching transistors to address the local bitlines and and a switching control unit for switching the switching transistors accordingly.

6. The memory device according to claim 1, whereby the memory cells are NROMs.

7. The memory device according to claim 1, further comprising:
a sensing circuit, comprising two sections, whereby the first section is a pre-charge circuit to apply the first potential to the source terminals and the second section is an I-V-conversion circuit to translate a measured source current into a voltage signal.

8. The memory device according to claim 7, further comprising a reference cell, which is connected to the voltage supply and which current is measured and compared with the sensed current of the memory cell by the sensing circuit.

9. The memory device according to claim 7, whereby the first and the second section of the sensing circuit are connected via a connecting transistor.

10. The memory device according to claim 9, whereby the connecting transistor is off while applying the first potential to the source terminals of the memory cells.

11. The memory device according to claim 7, whereby the pre-charge circuit comprises a first cascode voltage transistor to stabilize the first potential.

12. The memory device according to claim 7, whereby the I-V-conversion circuit comprises a first PMOS transistor acting as a first current source and a second PMOS transistor acting as a second current source, each PMOS transistor being biased with the same gate voltage and having the same supply voltage at corresponding drain terminals, thereby providing the same bias current, the source terminal of the first PMOS transistor being connected to a drain terminal of a second cascode voltage transistor, which source terminal being connected to the bitline of the memory cell and to the drain terminal of a first NMOS transistor, acting as one part of a current mirror, the source terminal of the second PMOS transistor being connected to the drain terminal of a third cascode voltage transistor, which source terminal being connected to the drain terminal of a second NMOS transistor, acting as second part of the current mirror;
wherein the gate terminals of the first NMOS transistor and the second NMOS transistor are connected to the source terminal of the first PMOS transistor and the drain terminal of the first cascode voltage transistor; and
the drain terminal of the reference cell being connected to the source terminal of the second PMOS transistor.

13. The memory device according to claim 12, further comprising a comparator, which inputs are connected to the source terminal of the second PMOS transistor and to a reference node respectively and providing at its output an output voltage.

14. The memory device according to claim 1, whereby a local feedback cascode, which stabilizes the first potential, is connected to the bitlines.

15. The memory device according to claim 14, whereby the local feedback cascode comprises a cascode transistor, which gate is controlled via an operational amplifier output, which compares on its inputs the voltage at the bitlines with a predetermined voltage value, and which source terminal is contacted to the bitlines and to a sink transistor acting as a current sink for a bias current, and which drain terminal is contacted with the source terminal of a first PMOS mirror transistor, which provides a current that is the bias current minus the current through a reference cell.

16. The memory device according to claim 15, whereby a first input of a comparator is connected to the drain terminal of the cascode transistor and a second input of the comparator is connected to the the output of a second PMOS mirror transistor and to the input of a reference mirror transistor and the output of the comparator delivers the output voltage.

17. A method for sensing a current output from a selected memory cell, situated in an array of further memory cells, to determine the conduction or non-conduction state of the memory cell, the method comprising:
applying a first potential to a source terminal of at least one adjacent further memory cell;
applying the first potential to a source terminal of the selected memory cell; and
applying a second potential to a drain terminal of the selected memory cell, and sensing the current output from the selected memory cell.

18. The method for sensing a current output from a selected memory cell according to claim 17, further comprising:
applying the first potential to the source terminals of every further memory cell before sensing.

19. The method for sensing a current output from a selected memory cell according to claim 17, further comprising:
applying the first potential to drain terminals of the further memory cells.

20. The method for sensing a current output from a selected memory cell according to claim 17, whereby the first potential is different from ground potential.

21. The method for sensing a current output from a selected memory cell according to claim 17, whereby the first potential is around 200 mV.

22. A method for sensing a current output from a selected memory cell according to claim 17, further comprising:
letting float the potential of source terminals of the further memory cells while sensing.

23. The method for sensing a current output from a selected memory cell according to claim 17, further comprising:
switching off switches which connect source terminals to a voltage source before sensing.

24. The method for sensing a current output from a selected memory cell according to claim 17, further comprising:
letting switches on, which connect drain and source terminal of the one of the memory cells to other voltage sources.

25. The method for sensing a current output from a selected memory cell according to claim 17, further comprising:
providing the memory cells being arranged in one block, which is electrically insulated from other blocks; and
applying the first potential only to source terminals of further memory cells within the block of the one of the memory cells.

26. The method for sensing a current output from a selected memory cell according to claim 17, further comprising:
sensing the current in a DC sensing scheme.

27. The method for sensing a current output from a selected memory cell according to claim 17, further comprising:
applying the first potential to every source terminal after sensing.

28. The method for sensing a current output from a selected memory cell according to claim 17, further comprising:
sensing the current by directly measuring the source current of the memory cell.

29. The method for sensing a current output from a selected memory cell according to claim 17, further comprising:
providing a single reference cell for several columns of memory cells, comparing the current through the single reference cell with the current through the sensed memory cell.

30. The method according to claim 17, further comprising:
providing a pre-charge circuit for applying the first potential to the source terminals and providing an I-V-conversion circuit for conversion of the measured current through the sensed memory cell into an output voltage, whereby while applying the first potential to the source terminals a connecting transistor between the pre-charge circuit and the I-V-conversion circuit is switched off.

31. The method according to claim 30, further comprising switching on the I-V-conversion circuit before the application of the first potential to the source terminals is finished.

32. The method according to claim 31, further comprising switching on the connecting transistor after the first potential is applied to all source terminals.

33. The method according to claim 17, further comprising providing a local feedback cascode, for applying the first potential to the source terminals of the memory cells.

34. A sensing circuit comprising two sections, comprising:
a first section is a pre-charge circuit to apply a first potential to source terminals of memory cells; and
a second section is an I-V-conversion circuit to translate a measured source current into a voltage signal.

35. The sensing circuit according to claim 34, whereby the first and the second section of the sensing circuit are connected via a connecting transistor.

36. The sensing circuit according to claim 35, whereby the connecting transistor is off while applying the first potential to the source terminals of the memory cells.

37. The sensing circuit according to claim 34, whereby the pre-charge circuit comprises a first cascode voltage transistor to stabilize the first potential.

38. The sensing circuit according to claim 34, whereby the I-V-conversion circuit comprises a first PMOS transistor acting as a first current source and a second PMOS transistor acting as a second current source, each PMOS transistor being biased with the same gate voltage and having the same supply voltage at corresponding drain terminals, thereby providing the same bias current, the source terminal of the first PMOS transistor being connected to a drain terminal of a second cascode voltage transistor, which source terminal being connected to the bitline of the memory cell and to the drain terminal of a first NMOS transistor, acting as one part of a current mirror, the source terminal of the second PMOS transistor being connected to the drain terminal of a third cascode voltage transistor, which source terminal being connected to the drain terminal of a second NMOS transistor, acting as second part of the current mirror, the gate terminals of the first NMOS transistor and the second NMOS transistor being connected to the source terminal of the first PMOS transistor and the drain terminal of the first cascode voltage transistor; and
the drain terminal of the reference cell being connected to the source terminal of the second PMOS transistor.

39. The sensing circuit according to claim 38, further comprising a comparator, which inputs are connected to the source terminal of the second PMOS transistor and to a reference node respectively and providing at its output an output voltage.

40. A sensing circuit comprising:
a local feedback cascode, which stabilizes a first potential, is connected to bitlines of a memory cell; and
the local feedback cascode comprises a cascode transistor, which gate is controlled via an operational amplifier output, which compares on its inputs the voltage at the bitlines with a predetermined voltage value, and which source terminal is contacted to the bitlines and to a sink transistor acting as a current sink for a bias current, and which drain terminal is contacted with the source terminal of a first PMOS mirror transistor, which provides a current that is the bias current minus the current through a reference cell.

41. The sensing circuit according to claim 40, whereby a first input of a comparator is connected to the drain terminal of the cascode transistor and a second input of the comparator is connected to the output of a second PMOS mirror transistor and to the input of a reference mirror transistor and the output of the comparator delivers the output voltage.

42. A memory device, comprising:
a sensing circuit, comprising two sections, whereby a first section is a pre-charge circuit to apply a first potential to source terminals of memory cells and a second section is an I-V-conversion circuit to translate a measured source current of the memory cell into a voltage signal.

43. A memory device, comprising:
a local feedback cascode, which stabilizes a first potential, is connected to bitlines of the memory device; and
the local feedback cascode comprises a cascode transistor, which gate is controlled via an operational amplifier output, which compares on its inputs the voltage at the bitlines with a predetermined voltage value, and which source terminal is contacted to the bitlines and to a sink transistor acting as a current sink for a bias current, and which drain terminal is contacted with the source terminal of a first PMOS mirror transistor, which provides a current that is the bias current minus the current through a reference cell.

44. A memory device, comprising:
a plurality of memory cells, whereby each memory cell comprises a drain terminal and a source terminal; and
a voltage supply for providing, before sensing a current through a selected memory cell, a first voltage to at least the source and the drain terminal of a neighboring memory cell, which drain terminal is connected to a source terminal of the selected memory cell; and for providing the first voltage to the source terminal of the selected memory cell while sensing the current.

45. A memory device comprising:
a plurality of memory cells, whereby each memory cell comprises a drain terminal and a source terminal, the memory cells being arranged in an array of rows and columns, whereby the source terminals of the memory cells arranged in one of the columns are connected via respective bitlines;
means for providing a voltage supply for providing a first voltage to every bitline of the memory device before sensing the condition of a selected memory cell, and for providing a second voltage to the drain terminal of the selected memory cell; and
means for providing a sensing device for sensing the current output of the source terminal of the selected memory cell.
